(19) United States
(12) Patent Application Publication
(10) Pub. No.: US 2025/0223156 A1
(43) Pub. Date: Jul. 10, 2025

(54) CONSTANT CHARGE OR CAPACITANCE FOR CAPACITIVE MICRO-ELECTRICAL-MECHANICAL SYSTEM SENSORS

(71) Applicant: INVENSENSE, INC., San Jose, CA (US)

(72) Inventor: Joseph Seeger, MENLO PARK, CA (US)

(21) Appl. No.: 19/092,888

(22) Filed: Mar. 27, 2025

Related U.S. Application Data
(63) Continuation of application No. 18/066,802, filed on Dec. 15, 2022, now Pat. No. 12,286,342.
(60) Provisional application No. 63/291,604, filed on Dec. 20, 2021.

(51) Int. Cl. B81B 7/02; H02M 3/07

(52) U.S. Cl. CPC B81B 7/02; H02M 3/07; B81B 2201/0221; B81B 2201/0257; B81B 2203/04; B81B 2207/03

(57) ABSTRACT

Embodiments for constant charge or capacitance for capacitive micro-electro-mechanical system (MEMS) sensors are presented herein. A MEMS device comprises a sense element circuit comprising a bias resistance, a charge-pump, and a capacitive sense element comprising an electrode and a sense capacitance. The charge-pump generates, at a bias resistor electrically coupled to the electrode, a bias voltage that is inversely proportional to a capacitance value comprising a value of the sense capacitance to facilitate maintenance of a nominally constant charge on the electrode. A sensing circuit comprises an alternating current (AC) signal source that generates an AC signal at a defined frequency; and generates, based on the AC signal, an AC test voltage at a test capacitance that is electrically coupled to the electrode. The sense element circuit generates, based on the AC test voltage at the defined frequency, an output signal representing the value of the sense capacitance.

### CROSS-REFERENCE TO RELATED APPLICATION

This patent application claims priority to U.S. patent application Ser. No. 18/066,802, filed on Dec. 15, 2022, and entitled “CONSTANT CHARGE OR CAPACITANCE FOR CAPACITIVE MICRO-ELECTRICAL-MECHANICAL SYSTEM SENSORS”, which claims priority to U.S. Provisional Patent Application No. 63/291,604, filed on Dec. 20, 2021, and entitled “CONSTANT CHARGE FOR CAPACITIVE MEMS SENSORS”; the entirety of the aforementioned application is hereby incorporated by reference herein.

### TECHNICAL FIELD

The subject disclosure generally relates to embodiments for constant charge or capacitance for capacitive micro-electro-mechanical system (MEMS) sensors.

### BACKGROUND

Conventional MEMS microphone technologies apply a bias voltage to a membrane of a MEMS microphone-the bias voltage creating charge on the membrane, which converts capacitance changes due to applied sound pressure into an output voltage.

The bias voltage also creates an electrostatic force that pulls the membrane towards a backplate. When too much bias voltage is applied, a corresponding increase in electrostatic force will cause the membrane to snap, or collapse, to the backplate. The amount of bias voltage that causes the membrane to snap to the backplate is called a “collapse” or “pull-in” voltage. Typically, a bias voltage of approximately 70-80% of the pull-in voltage is applied to avoid collapse of the membrane. Appling higher bias to the membrane increases the charge on the membrane, which correspondingly leads to an increase in output voltage representing the sound pressure. Although it is desired to increase the bias voltage as much as possible to improve microphone sensitivity and improve a signal-to-noise-ratio (SNR) of the MEMS microphone, increasing the bias voltage to, and/or past, the pull-in voltage causes the MEMS microphone to be unstable and/or inoperable.

In this regard, conventional MEMS microphone technologies have had some drawbacks, some of which may be noted with reference to the various embodiments described herein below.

### BRIEF DESCRIPTION OF THE DRAWINGS

Non-limiting embodiments of the subject disclosure are described with reference to the following Figures, wherein like reference numerals refer to like parts throughout the various views unless otherwise specified:

FIG. 1 illustrates a block diagram of a MEMS device that applies a nominally constant charge to a capacitive sense element of the MEMS device, or facilitates maintenance of a nominally constant capacitance value of a sense capacitance of the capacitive sense element, in accordance with various example embodiments;

FIGS. 2-3 illustrates block diagrams of respective MEMS device circuits that apply respective nominally constant charges to capacitive sense elements of the respective MEMS device circuits, in accordance with various example embodiments;

FIGS. 4-5 illustrates block diagrams of respective MEMS device circuits that include respective amplifiers electrically coupled to respective test capacitances—the respective MEMS devices applying respective nominally constant charges to capacitive sense elements of the respective MEMS device circuits, in accordance with various example embodiments;

FIGS. 6-7 illustrates block diagrams of respective MEMS device circuits that include respective summing amplifiers electrically coupled to respective test capacitances—the respective MEMS devices applying respective nominally constant charges to capacitive sense elements of the respective MEMS device circuits, in accordance with various example embodiments;

FIG. 8 illustrates a block diagram of a MEMS device circuit including a differential output-the MEMS device applying a nominally constant charge to a capacitive sense element of the MEMS device, in accordance with various example embodiments;

FIG. 9 illustrates a block diagram of a MEMS device circuit that facilitates maintenance of a nominally constant capacitance value of a sense capacitance of a capacitive sense element of the MEMS device, in accordance with various example embodiments.

FIG. 10 illustrates a block diagram of a MEMS device circuit that includes an amplifier electrically coupled to a test capacitance—the MEMS device facilitating maintenance of a nominally constant capacitance value of a sense capacitance of a capacitive sense element of the MEMS device, in accordance with various example embodiments.

FIG. 11 illustrates a block diagram of a MEMS device circuit that includes a summing amplifier electrically coupled to a test capacitance—the MEMS device facilitating maintenance of a nominally constant capacitance value of a sense capacitance of a capacitive sense element of the MEMS device, in accordance with various example embodiments.

FIG. 12 illustrates a plot of normalized charge versus normalized bias voltage of a MEMS device, in accordance with various example embodiments;

FIG. 13 illustrates a small-signal model of a MEMS device, in accordance with various example embodiments;

FIG. 14 illustrates a bode diagram of a constant capacitance filter of a MEMS device, in which the MEMS device facilitates maintenance of a nominally constant capacitance value of a sense capacitance of a capacitive sense element of the MEMS device, in accordance with various example embodiments; and

FIG. 15 illustrates a process performed by a MEMS device with respect to applying a nominally constant charge to a capacitive sense element of the MEMS device, in accordance with various example embodiments.

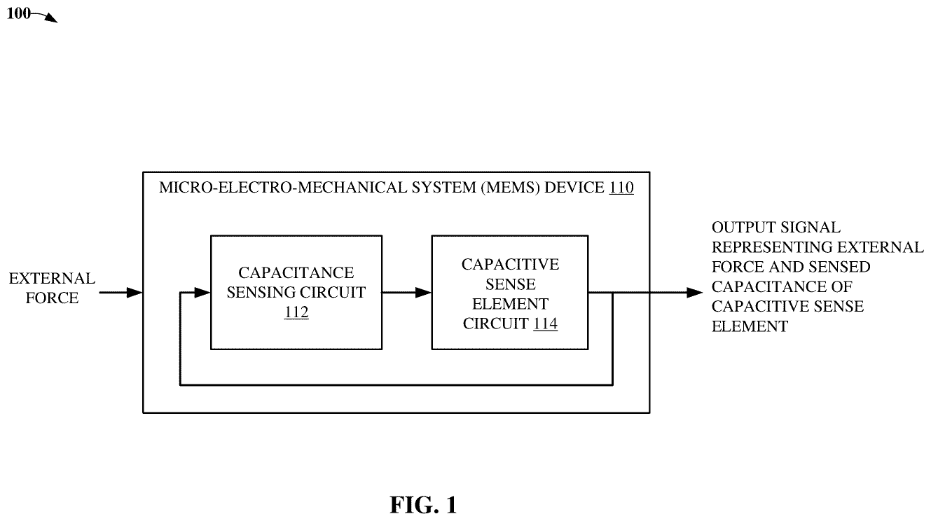

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

Conventional microphone technologies have had some drawbacks with respect to being unstable and/or inoperable when a bias voltage that has been applied to a membrane of a MEMS microphone is at, or exceeds, a pull-in voltage of the MEMS microphone. Various embodiments disclosed herein can enable biasing a membrane of a MEMS device closer to, or beyond, the pull-in voltage by applying a nominally constant charge to a capacitive sense element of the MEMS device, or by maintaining a nominally constant capacitance value of a sense capacitance of the capacitive sense element.

For example, in embodiment(s), a MEMS device comprises: a capacitance sensing circuit (112) comprising a demodulator (260) comprising a first demodulator input that is electrically coupled to an alternating current (AC) signal source (240) that generates an AC signal at a defined frequency, and a test capacitance (250) that is electrically coupled to the AC signal.

Further, the MEMS device comprises a capacitance sense element circuit (114) comprising: a capacitive sense element (230) comprising an electrode (222) and a sense capacitance (C_{MEMS}), and a charge pump (210) that generates a bias voltage that is electrically coupled, via a bias resistance (220), to the electrode (222) of the capacitive sense element (230), wherein the bias voltage is proportional to an inverse value of the sense capacitance (C_{MEMS}), wherein the test capacitance (250) is electrically coupled to the electrode (222) of the capacitive sense element (230), wherein a capacitance sensing circuit output of the capacitance sensing circuit (112) is electrically coupled to the charge pump (210), and wherein an output (Vo) of the capacitive sense element circuit (114) is electrically coupled to a second demodulator input of the demodulator (260) and represents a value of the sense capacitance (C_{MEMS}).

In other embodiment(s), the bias voltage facilitates maintenance of a nominally constant charge on the electrode (222) of the capacitive sense element (230).

In yet other embodiment(s), the capacitance sensing circuit (112) further comprises a gain circuit (270) comprising a low-pass filter (272) that is electrically coupled to a gain stage amplifier (274) of the gain circuit; and the demodulator (260) is electrically coupled, via the gain circuit (270), to the charge pump (210).

In embodiment(s), the gain stage comprises a defined gain, and the nominally constant charge is proportional to the defined gain.

In other embodiment(s), the capacitance sensing circuit (112) further comprises a gain circuit (970) comprising a difference circuit (910) that is electrically coupled to a filter (920) of the gain circuit, wherein the demodulator (260) is electrically coupled, via the gain circuit (970), to the charge pump (210), and wherein the gain circuit facilitates, based on a reference signal (Vref), maintenance of a nominally constant capacitance value of the sense capacitance (C_{MEMS}).

In yet other embodiment(s), a demodulator output of the demodulator (260) nominally equals the reference signal (Vref) to facilitate maintenance of the nominally constant capacitance value of the sense capacitance.

In embodiment(s), the capacitive sense element is biased in a negative capacitance region.

In other embodiment(s), the MEMS device further comprises a bootstrap capacitance (336) that is electrically coupled between the electrode (222) of the capacitive sense element (230) and the output (Vo) of the capacitive sense element circuit (114).

In yet other embodiment(s), the bootstrap capacitance (336) facilitates reducing noise of the output (Vo) of the capacitive sense element circuit (114) in response to the capacitive sense element (230) being biased in the negative capacitance region.

In embodiment(s), the defined frequency is greater than a resonant frequency of the capacitive sense element.

In other embodiment(s), a first portion of the output (Vo) of the capacitive sense element circuit (114) represents an external force that has been applied to a membrane of the capacitive sense element; and a second portion of the output (Vo) of the capacitive sense element circuit represents a measurement of the value of the sense capacitance.

In yet other embodiment(s), the MEMS device further comprises an amplifier (410) that is electrically coupled between the AC signal source and the test capacitance, and that generates, based on the AC signal, the AC test voltage at a test capacitance input of the test capacitance.

In embodiment(s), the amplifier comprises a summing amplifier (610) comprising a first amplifier input, a second amplifier input, and an amplifier output, wherein the first amplifier input is electrically coupled to the AC signal, wherein the second amplifier input is electrically coupled to the output (Vo) of the capacitive sense element circuit, and wherein the amplifier output is electrically coupled to the test capacitance input.

In other embodiment(s), an amplitude of the second portion of the output (Vo) of the capacitive sense element circuit is inversely proportional to the value of the sense capacitance.

In yet other embodiment(s), the capacitive sense element circuit (114) further comprises an inverting buffer (820) that generates an inverted output signal that is based on the output (Vo) of the capacitive sense element circuit.

In embodiment(s), the MEMS device further comprises a difference circuit (810), wherein a first difference circuit input of the difference circuit is electrically coupled to the output (Vo) of the capacitive sense element circuit, wherein a second difference circuit input of the difference circuit is electrically coupled to the inverted output signal, and wherein the output (Vo) of the capacitive sense element circuit (114) is electrically coupled to the second demodulator input via a difference circuit output of the difference circuit.

In other embodiment(s), the MEMS device further comprises a summing amplifier (610) comprising a first amplifier input, a second amplifier input, and an amplifier output, wherein the first amplifier input is electrically coupled to the AC signal, wherein the second amplifier input is electrically coupled to the output (Vo) of the capacitive sense clement circuit, and wherein the amplifier output is electrically coupled to the test capacitance input.

In embodiment(s), a MEMS device (110), e.g., microphone, accelerometer, pressure sensor, ultrasonic receiver, gyroscope, or other type of vibration sensing device, comprises a capacitive sense element circuit (114) comprising a bias resistance (220) comprising a resistance input and a resistance output, a charge-pump (210) comprising a charge pump input and a charge pump output, and a capacitive sense element (230) comprising an electrode (222) and a sense capacitance, in which the charge-pump output generates a bias voltage at the resistance input, the resistance output is electrically coupled to the electrode of the capacitive sense element, and the bias voltage is proportional to an inverse of a capacitance value comprising the value of the sense capacitance to facilitate maintenance of a nominally constant charge on the electrode of the capacitive sense element.

The MEMS device further comprises a capacitance sensing circuit (112) comprising: a gain circuit (270); a demodulator (260) that modulates a first demodulator input and a second demodulator input to obtain a demodulator output that is electrically coupled, via the gain circuit, to the charge pump input; an alternating current (AC) signal source (240) that generates an AC signal (e.g., an analog voltage; a digital waveform) at a defined frequency, in which the AC signal is electrically coupled to the first demodulator input; and a test capacitance (250) comprising a test capacitance input and a test capacitance output.

The capacitance sensing circuit generates, based on the AC signal at the defined frequency, an AC test voltage at the test capacitance input. The test capacitance output is electrically coupled to the electrode of the capacitive sense element. The capacitive sense element circuit generates, based on the AC test voltage at the defined frequency, an output signal that is electrically coupled to the second demodulator input and that represents a value of the sense capacitance.

In embodiment(s), the defined frequency is greater than a resonant frequency of the capacitive sense element. In other embodiment(s), the defined frequency is in a range of about 50 kHz to about 1 MHZ.

In yet other embodiment(s), a first portion of the output signal of the capacitive sense clement circuit represents an external force that has been applied to a membrane of the capacitive sense element, and a second portion of the output signal of the capacitive sense element circuit represents a measurement of the value of the sense capacitance.

In embodiment(s), an amplifier (410) is electrically coupled between the AC signal source and the test capacitance, and generates, based on the AC signal, the AC test voltage at the test capacitance input.

In yet other embodiment(s), the amplifier comprises a summing amplifier (610) comprising a first amplifier input, a second amplifier input, and an amplifier output, in which the first amplifier input is electrically coupled to the AC signal, the second amplifier input is electrically coupled to the output signal of the capacitive sense element circuit, and the amplifier output is electrically coupled to the test capacitance input—the summing amplifier generating, via the amplifier output based on the AC signal, the AC test voltage at the test capacitance input.

In embodiment(s), an amplitude of the second portion of the output signal of the capacitive sense element circuit is inversely proportional to the value of the sense capacitance.

In embodiment(s), the capacitive sense element circuit further comprises an inverting buffer (820) that generates an inverted output signal that is based on the output signal of the capacitance sense element circuit, in which a differential output signal of the capacitive sense clement circuit is represented by the output signal and the inverted output signal. The capacitance sensing circuit further comprises a difference circuit (810) that comprises a first difference circuit input, a second difference circuit input, and a difference circuit output. The first difference circuit input is electrically coupled to the output signal of the capacitive sense element circuit, the second difference circuit input is electrically coupled to the inverted output signal, and the difference circuit output is electrically coupled to the second demodulator input of the demodulator.

In other embodiment(s), the gain circuit comprises a low-pass filter (272) electrically coupled to a gain stage (274) comprising a defined gain, in which the nominally constant charge is proportional to the defined gain; and.

In yet other embodiment(s), the MEMS device further comprises a bootstrap capacitance (336) that is electrically coupled between the electrode of the capacitive sense clement and the output signal of the capacitive sense element circuit. In embodiment(s), the bootstrap capacitance facilitates reducing noise of the output signal of the capacitive sense element circuit in response to the capacitive sense element being biased in a negative capacitance region.

In other embodiment(s), a MEMS device (110), e.g., microphone, accelerometer, pressure sensor, ultrasonic receiver, gyroscope, or other type of vibration sensing device, comprises: a capacitive sense element circuit (114) comprising a bias resistance (220) comprising a resistance input and a resistance output, a charge-pump (210) comprising a charge pump input and a charge pump output, and a capacitive sense element (230) comprising an electrode (222) and a sense capacitance, in which the charge-pump output generates a bias voltage at the resistance input, and the resistance output is electrically coupled to the electrode of the capacitive sense element.

The MEMS device further comprises a capacitance sensing circuit (112) comprising: a gain circuit (970) that comprises a difference circuit (910) and a filter (920); a demodulator (260) that modulates a first demodulator input and a second demodulator input to obtain a demodulator output that is electrically coupled, via the gain circuit, to the charge pump input; an AC signal source (240) that generates an AC signal (e.g., an analog voltage; a digital waveform) at a defined frequency, in which the AC signal is electrically coupled to the first demodulator input; and a test capacitance (250) comprising a test capacitance input and a test capacitance output.

The capacitance sensing circuit generates, based on the AC signal at the defined frequency, an AC test voltage at the test capacitance input. The test capacitance output is electrically coupled to the electrode of the capacitive sense element. The capacitive sense element circuit generates, based on the AC test voltage at the defined frequency, an output signal that is electrically coupled to the second demodulator input and that represents a value of the sense capacitance.

The demodulator output is electrically coupled to a first input of the difference circuit, a reference signal is electrically coupled to a second input of the difference circuit, a difference output of the difference circuit is electrically coupled, via the filter, to the charge-pump input, and the demodulator output nominally equals the reference signal to facilitate maintenance of a nominally constant value of the sense capacitance.

In yet other embodiment(s), the defined frequency is greater than a resonant frequency of the capacitive sense element. In embodiment(s), the defined frequency is in a range of about 50 kHz to about 1 MHZ.

In other embodiment(s), a first portion of the output signal of the capacitive sense element circuit represents an external force that has been applied to a membrane of the capacitive sense element, and a second portion of the output signal of the capacitive sense element circuit represents a measurement of the value of the sense capacitance.

In embodiment(s), a first magnitude of a sum of respective DC component values of the sense capacitance and the test capacitance is inversely proportional to a second magnitude of a second DC component of the reference signal.

In other embodiment(s), an amplifier (410) is electrically coupled between the AC signal source and the test capacitance, and generates, based on the AC signal, the AC test voltage at the test capacitance input.

In yet other embodiment(s), the amplifier comprises a summing amplifier (610) comprising a first amplifier input, a second amplifier input, and an amplifier output, in which the first amplifier input is electrically coupled to the AC signal, the second amplifier input is electrically coupled to the output signal of the capacitive sense element circuit, and the amplifier output is electrically coupled to the test capacitance input—the summing amplifier generating, via the amplifier output based on the AC signal, the AC test voltage at the test capacitance input.

In other embodiment(s), an amplitude of the second portion of the output signal of the capacitive sense element circuit is inversely proportional to the value of the sense capacitance.

In embodiment(s), the MEMS device further comprises a bootstrap capacitance (336) that is electrically coupled between the electrode of the capacitive sense clement and the output signal of the capacitive sense element circuit. In other embodiment(s), the bootstrap capacitance facilitates reducing noise of the output signal of the capacitive sense element circuit in response to the capacitive sense element being biased in a negative capacitance region.

In yet other embodiment(s), a method comprises detecting a value of a sense capacitance of a capacitive sense element of a MEMS device; generating a continuous time bias voltage that is inversely proportional to a capacitance value comprising the value of the sense capacitance; and in response to applying the continuous time bias voltage to the capacitive sense element, generating a nominally constant charge on the capacitive sense element.

In embodiment(s), the detecting of the value of the sense capacitance comprises applying an AC test voltage at a defined frequency to a test capacitance input of a test capacitance, in which a test capacitance output of the test capacitance is electrically coupled to the capacitive sense element, and an output signal of the MEMS device represents, based on the AC test voltage at the defined frequency, the value of the sense capacitance.

In other embodiment(s), the applying of the AC test voltage to the test capacitance input further comprises applying the AC test voltage to the test capacitance input in a frequency range of about 50 kHz to about 1 MHz.

In yet other embodiment(s), the method further comprises in response to biasing the capacitance of the capacitive sense element in a negative capacitance region, reducing, via a bootstrap capacitance that is electrically coupled to an output signal of the MEMS device, a noise of the output signal of the MEMS device.

Ideally, a capacitance (C_{MEMS}) of the capacitive sense element depends on an electrode area (A) of an electrode of the capacitive sense element and a gap (g) between the electrode and a backplate of the capacitive sense element:

$${C}_{MEMS} = \frac{ϵ A}{g} .$$

The gap depends on initial gap (g₀), external force (F, i.e., sound pressure), charge (q), and membrane stiffness (k):

$$g = {g}_{0} - \frac{F}{k} - \frac{1}{2} \frac{{q}^{2}}{ϵ Ak} .$$

The gap decreases with charge; and the capacitance increases with charge.

The voltage across the capacitive sense element depends on the charge and the capacitance of the capacitive sense element:

$$V = q \frac{g}{ϵ A} = \frac{q}{ϵ A} ( {g}_{0} - \frac{F}{k} - \frac{1}{2} \frac{{q}^{2}}{ϵ Ak} ) .$$

The voltage across the capacitive sense element changes due to charge, q, and due to changes in an external force (F), e.g., sound pressure, which has been applied to the capacitive sense element.

To increase a sensitivity of the capacitive sense element—represented by a change in the voltage across the capacitive sense element due to a change in force, e.g., sound pressure, which has been applied to the capacitive sense element—it is desirable to increase the charge (q) that is applied to the electrode.

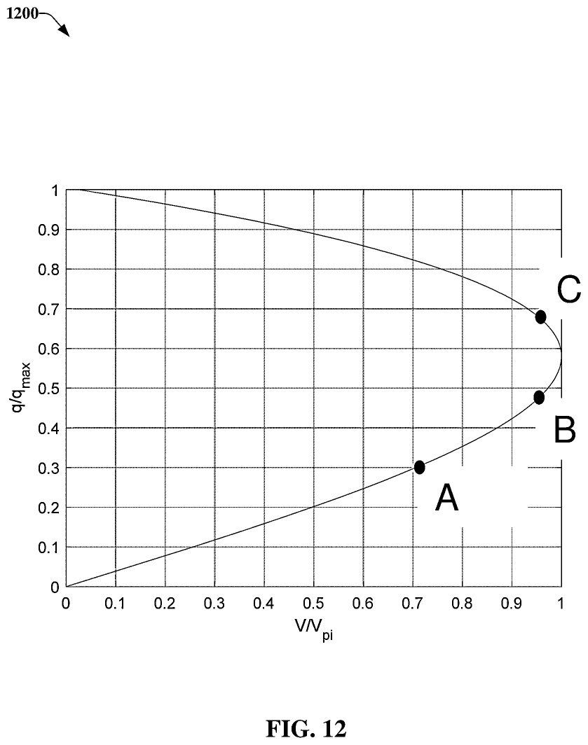

Referring now to FIG. 12, a plot (1200) of normalized charge versus normalized bias voltage (at zero force) of a conventional MEMS device, e.g., microphone, is illustrated, in accordance with various example embodiments. The maximum bias voltage that can be applied, via conventional technologies, to the conventional MEMS device is a pull-in voltage of “Vpi”, e.g., represented by a ratio of 1 on the plot.

Point “A” represents a typical bias point of a conventional MEMS device, which is approximately 70% of the pull-in voltage.

Point “B” represents a higher bias voltage and charge, which has been applied to the conventional MEMS device, than bias voltage and charge that has been applied to the conventional MEMS device at point A; therefore, point B represents a higher capacitance and higher sensitivity of the conventional MEMS device than capacitance and sensitivity of the conventional MEMS device corresponding to point A.

Under ideal conditions, the conventional MEMS device is stable with an applied bias voltage corresponding to point B; however, because such bias voltage is near the pull-in voltage, the conventional MEMS device is likely to be unstable in practice due to parameter variation(s) of the conventional MEMS device that occur over process and temperature changes.

Point “C” represents a bias point corresponding to a charge, a sensitivity, and a capacitance that are higher than respective charges, sensitivities, and capacitances represented by bias points A and B; however, point C it is beyond the pull-in voltage, and therefore the conventional MEMS device is unstable with a constant bias voltage being applied at point C.

As conventional capacitive-based sensor technologies utilize a constant voltage source to bias a capacitive sense element, FIG. 12 illustrates that such technologies are limited in an amount of charge that can be applied to the capacitive sense element, and thus in an amount of sensitivity that can be achieved—due to instability corresponding to the pull-in voltage.

On the other hand, various embodiments disclosed herein can enable improved biasing of a membrane of a MEMS device, e.g., beyond a pull-in voltage of the MEMS device, by facilitating maintenance of a nominally constant capacitance value of a sense capacitance of a capacitive sense element of the MEMS device, or by facilitating maintenance of a nominally constant capacitance value of the sense capacitance—enabling stable operation of the MEMS device at points A, B, and C illustrated in FIG. 12. Further, such embodiments facilitate improvement of a signal-to-noise ratio (SNR) of the MEMS device by biasing the MEMS device beyond the pull-in voltage/point.

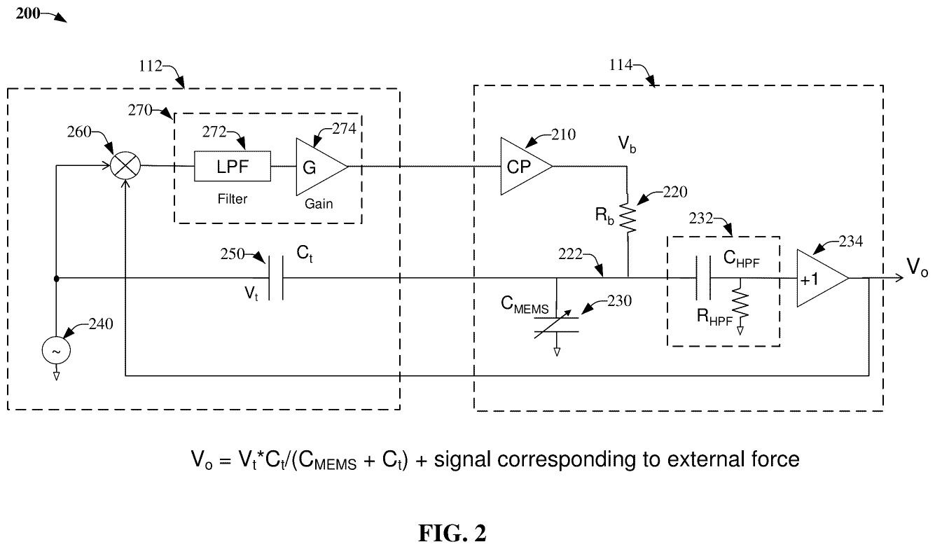

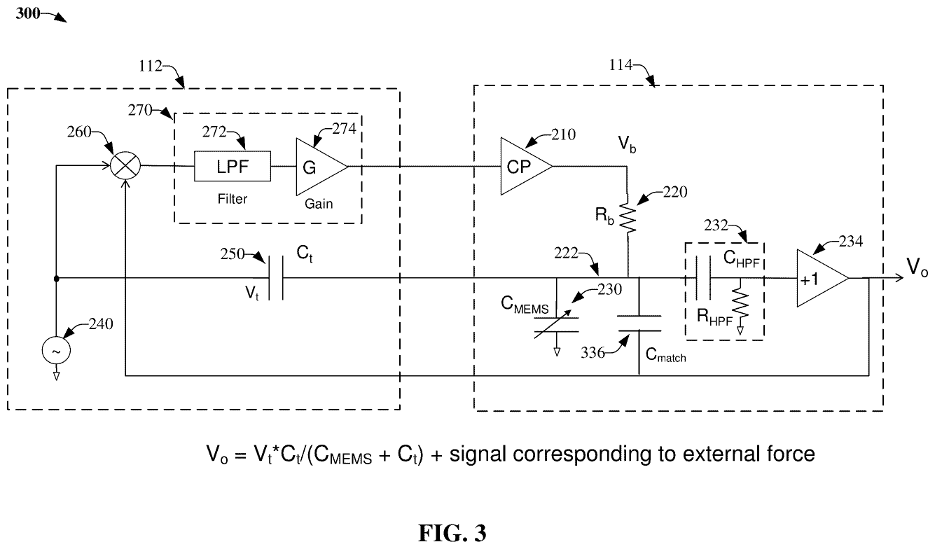

Referring now to FIGS. 2-3, block diagrams of respective MEMS device (110) circuits (200 and 300) that apply respective nominally constant charges to capacitive sense elements of the respective MEMS device circuits are illustrated, in accordance with various example embodiments.

The MEMS device (110), e.g., microphone, accelerometer, pressure sensor, ultrasonic receiver, gyroscope, or other type of vibration sensing device, comprises a capacitive sense element circuit (114) comprising a bias resistance (“R_{b}”) (220) comprising a resistance input and a resistance output, a charge-pump (“CP”) (210) comprising a charge pump input and a charge pump output, and a capacitive sense element (230) comprising an electrode (222) and a sense capacitance (“C_{MEMS}”), in which the charge-pump output generates a bias voltage (“V_{b}”) at the resistance input, and the resistance output is electrically coupled to the electrode of the capacitive sense element.

In embodiment(s), the electrode is electrically coupled to the membrane of the capacitive sense element. In yet other embodiment(s), the electrode is electrically coupled to a backplate of the capacitive sense element.

In embodiments, the electrode is electrically coupled to a high-pass filter (HPF) (232) that comprises a HPF resistance (“R_{HPF}”) and a HPF capacitance (“C_{HPF}”); and the HPF is electrically coupled to a unity gain buffer (234), which generates an output signal (“Vₒ”) of the capacitive sense element circuit.

In embodiments, the output of the test capacitance and an input of a bootstrap capacitance (336) are electrically coupled between the HPF and the unity gain buffer.

In yet other embodiment(s), a first portion of the output signal of the capacitive sense element circuit represents an external force (e.g., audio signal) that has been applied to a membrane of the capacitive sense element, and a second portion of the output signal of the capacitive sense clement circuit represents a measurement of the value of the sense capacitance.

In embodiment(s), the bias resistance ranges from about 1 giga-ohm to about 1 tera-ohm. In other embodiment(s), the bias voltage ranges from about 5 volts to about 20 volts.

The MEMS device further comprises a capacitance sensing circuit (112) comprising: a gain circuit (270); an AC signal source (240) that generates an AC signal (e.g., analog voltage; a digital waveform) at a defined frequency (e.g., being greater than a resonant frequency of the capacitive sense element; being in a range of about 50 kHz to about 1 MHZ); a demodulator (260) that modulates a first demodulator input and a second demodulator input to obtain a demodulator output that is electrically coupled, via the gain circuit, to the charge pump input; and a test capacitance (“Cₜ”) (250) comprising a test capacitance input and a test capacitance output.

The AC signal is electrically coupled to the first demodulator input and the test capacitance. The capacitance sensing circuit generates, based on the AC signal at the defined frequency, an AC test voltage (“Vₜ”) at the test capacitance input; and the test capacitance output is electrically coupled to the electrode of the capacitive sense element.

In turn, the capacitive sense element circuit generates, based on the AC test voltage at the defined frequency, the output signal—the output signal representing a value of the sense capacitance as follows:

$${V}_{o} = {V}_{t} ⋆ {C}_{t} / ( {C}_{MEMS} + {C}_{t} ) .$$

In embodiment(s), the demodulator rectifies Vₒ, e.g., multiplies Vₒ by a square wave at the same phase and frequency as Vₜ), resulting in a DC component of the demodulator output being equal to

$${V}_{demod} = \frac{2}{π} \frac{{V}_{t} {C}_{t}}{( {C}_{MEMS} + {C}_{t} )} .$$

In other embodiment(s), the gain circuit comprises a low-pass filter (“LPF”) (272) electrically coupled to a gain stage (274) comprising a defined gain “G”.

The demodulator, LPF, and gain stage provide a feedback signal to the charge-pump, in which the bias voltage is equal to

$${V}_{b} = \frac{2}{π} \frac{G {V}_{t} {C}_{t}}{( {C}_{MEMS +} {C}_{t )}} ,$$

so that the charge on test capacitance and the capacitive sense element of the MEMS device is ideally, or nominally, constant, being equal to

$$q = {V}_{b} ( {C}_{MEMS} + C t ) = \frac{2}{π} G {V}_{t} {C}_{t} .$$

Accordingly, the nominally constant charge (q_{MEMS}+q_{Ct}) is proportional to the defined gain G. In embodiment(s), if Cₜ less than 10% of C_{MEMS}, the charge on C_{MEMS} can be considered nominally constant.

In embodiment(s) illustrated by FIG. 3, the MEMS device further comprises a bootstrap capacitance (“C_{match}”) (336) that is electrically coupled between the electrode of the capacitive sense element and the output signal of the capacitive sense element circuit. The bootstrap capacitance is used to bootstrap Cₜ, e.g., to prevent, account for, improve upon, etc. reduced sensitivity and/or increased distortion.

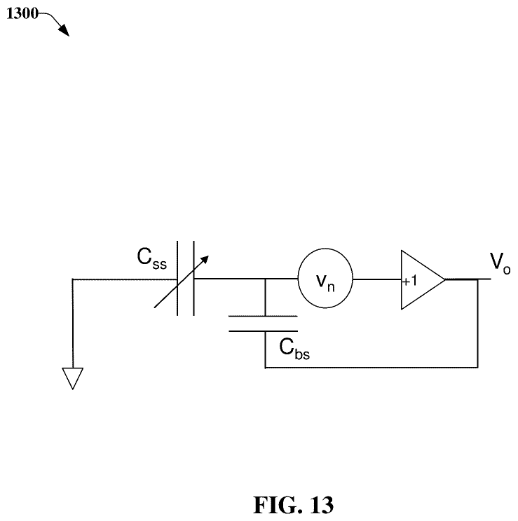

Referring now to FIG. 13, a block diagram (1300) of a small-signal model of a

MEMS device, e.g., microphone, comprising a capacitive sense element is illustrated, in accordance with various example embodiments.

Css represents a small-signal capacitance of the MEMS device.

Cbs is a capacitance that is bootstrapped by a unity gain buffer (“+1”).

Vₙ is a voltage source representing noise of the unity gain buffer.

In turn, the component of the output signal (“Vₒ”) due to noise is

$${V}_{o n} = ( 1 + \frac{{C}_{b s}}{{C}_{s s}} ) {V}_{n} ,$$

in which larger values of Css represent lower values of output signal noise.

Referring again to FIG. 12, the slope of the line representing the plot of normalized charge versus normalized bias voltage is the small signal capacitance representing the change in charge versus small changes in voltage given by

$$( \frac{d q}{d V} = {C}_{s s} ) .$$

In this regard, point A has a positive slope and positive value of Cₛₛ.

Point B has a larger slope than point A; and as the value of Cₛₛ at point B is larger than the value of Cₛₛ at point A, point B will have lower noise than point A.

Point C has a negative slope and therefore has a negative value of Cₛₛ.

If Cₛₛ is negative, e.g., at point C, the noise can be reduced, e.g., eliminated if Cₛₛ=−C_{bs}.

In this regard, in embodiment(s), the bootstrap capacitance (336) facilitates reducing noise of the output signal of the capacitive sense element circuit in response to the capacitive sense element being biased in a negative capacitance region, e.g., to achieve Cₛₛ=−C_{bs}.

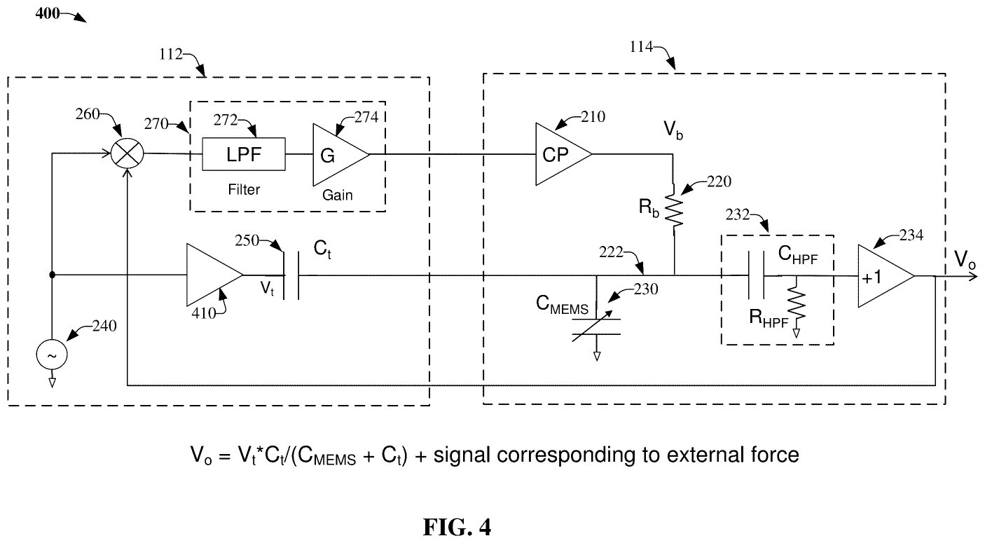

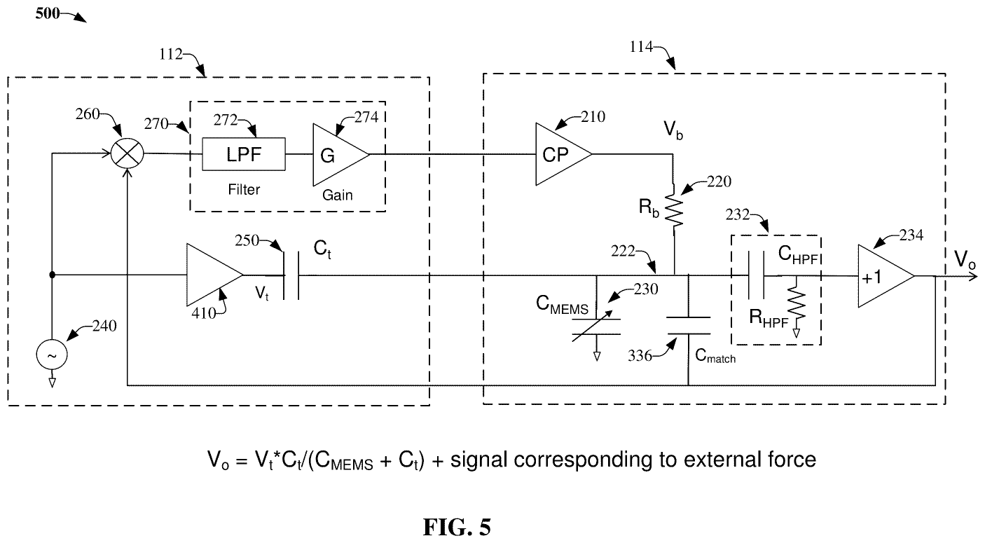

FIGS. 4-5 illustrate block diagrams of respective MEMS device circuits (400 and 500) that include respective amplifiers (410) electrically coupled to respective test capacitances (250)—the respective MEMS devices applying respective nominally constant charges to capacitive sense elements of the respective MEMS device circuits, in accordance with various example embodiments. In this regard, an amplifier (410) is electrically coupled between the AC signal source and the test capacitance (250), and the amplifier generates, based on the AC signal at the defined frequency, the test voltage (Vₜ).

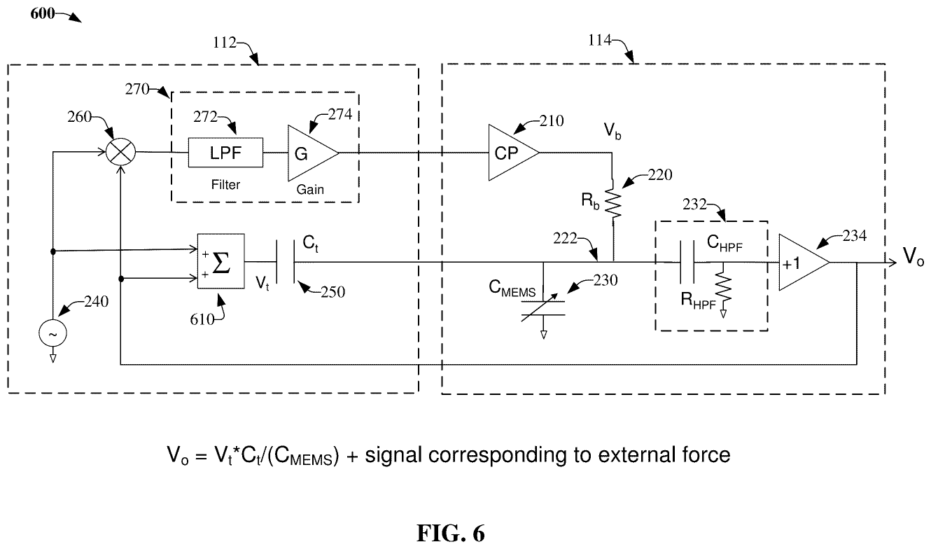

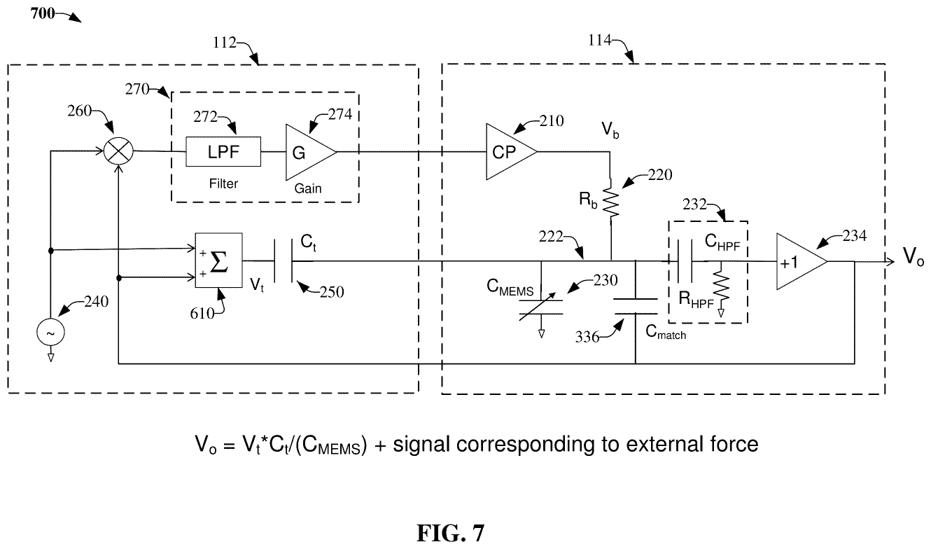

FIGS. 6-7 illustrates block diagrams of respective MEMS device circuits (600 and 700) that include respective summing amplifiers (610) electrically coupled to respective test capacitances (250)—the respective MEMS devices applying respective nominally constant charges to capacitive sense elements of the respective MEMS device circuits, in accordance with various example embodiments.

In turn, in embodiments with summing amplifier (610) the capacitive sense element circuit generates, based on the AC test voltage at the defined frequency, the output signal—the output signal representing a value of the sense capacitance as follows:

$${V}_{o} = {V}_{t} ⋆ {C}_{t} / ( {C}_{MEMS} ) .$$

In embodiment(s) with summing amplifier (610), the demodulator rectifies Vₒ, e.g., multiplies Vₒ by a square wave at the same phase and frequency as Vₜ, resulting in a DC component of the demodulator output being equal to

$${V}_{demod} = \frac{2}{π} \frac{{V}_{t} {C}_{t}}{{C}_{MEMS}} .$$

In embodiment(s) with the summing amplifier, the demodulator, LPF, and gain stage provide a feedback signal to the charge-pump, in which the bias voltage is equal to

$${V}_{b} = \frac{2}{π} \frac{{GV}_{t} {C}_{t}}{{C}_{MEMS}} ,$$

so that the charge on the capacitive sense element of the MEMS device is ideally, or nominally, constant, being equal to

$${q}_{MEMS} = {V}_{b} ( {C}_{MEMS} ) = \frac{2}{π} G {V}_{t} {C}_{t} .$$

Accordingly, the nominally constant charge (q_{MEMS}) is proportional to the defined gain G.

The summing amplifier (610) comprises a first amplifier input, a second amplifier input, and an amplifier output. The first amplifier input is electrically coupled to the AC signal, the second amplifier input is electrically coupled to the output signal of the capacitive sense element circuit, and the amplifier output is electrically coupled to the test capacitance input.

In this regard, the summing amplifier generates the test voltage based on the AC signal and the output signal of the capacitive sense element circuit-the output signal providing, via feedback to the summing amplifier, a positive loop gain <=1.

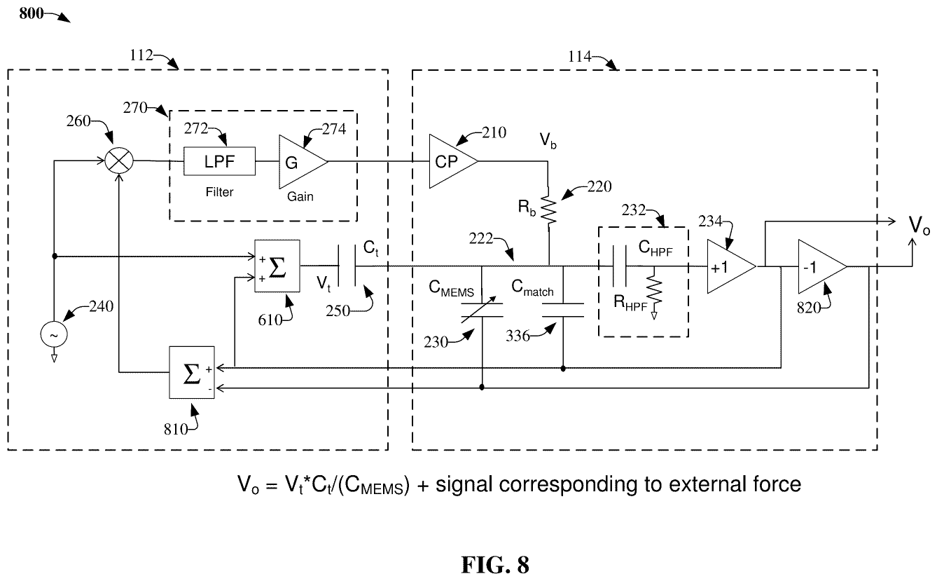

FIG. 8 illustrates a block diagram of a MEMS device circuit (800) including a differential output-the MEMS device applying a nominally constant charge to a capacitive sense element of the MEMS device, in accordance with various example embodiments. The capacitive sense element circuit comprises an inverting buffer (820) that generates an inverted output signal that is based on the output signal of the capacitance sense element circuit—a differential output signal, e.g., Vₒ, represented by the output signal and the inverted output signal.

The capacitance sensing circuit comprises a difference circuit (810) that comprises a first difference circuit input, a second difference circuit input, and a difference circuit output—the difference circuit facilitating subtraction of the first difference input and the second difference input. The first difference circuit input is electrically coupled to the output signal of the capacitive sense element circuit, the second difference circuit input is electrically coupled to the inverted output signal, the difference circuit output is electrically coupled to the second demodulator input of the demodulator.

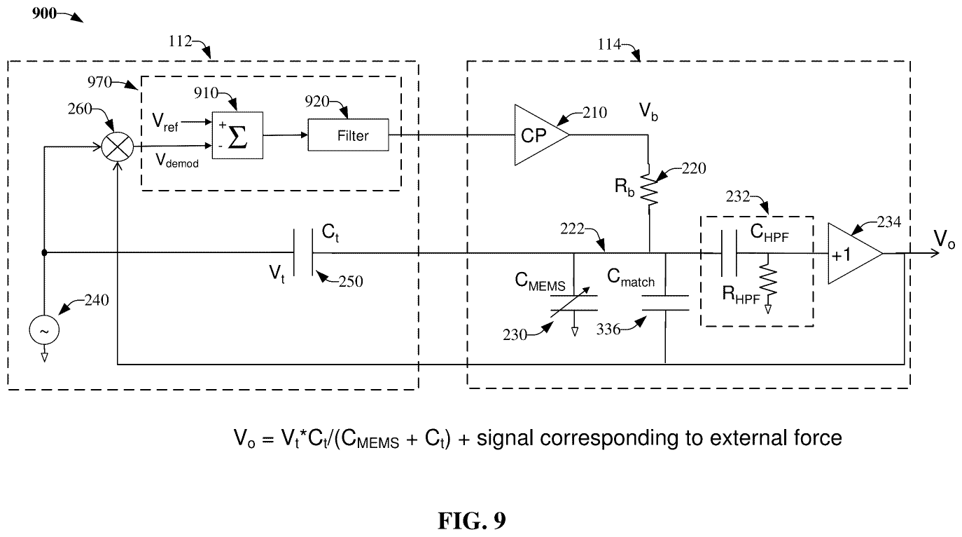

FIG. 9 illustrates a block diagram of a MEMS device circuit (900) that facilitates maintenance of a nominally constant capacitance value of a sense capacitance of a capacitive sense element of the MEMS device, in accordance with various example embodiments. The MEMS device (110), e.g., microphone, accelerometer, pressure sensor, ultrasonic receiver, gyroscope, or other type of vibration sensing device, comprises a capacitive sense element circuit (114) comprising a bias resistance (“R_{b}”) (220) comprising a resistance input and a resistance output, a charge-pump (“CP”) (210) comprising a charge pump input and a charge pump output, and a capacitive sense element (230) comprising an electrode (222) and a sense capacitance (“C_{MEMS}”). The charge-pump output generates a bias voltage (“V_{b}”) at the resistance input, and the resistance output is electrically coupled to the electrode of the capacitive sense element.

In other embodiment(s), the electrode is electrically coupled to the membrane of the capacitive sense element. In yet other embodiment(s), the electrode is electrically coupled to a backplate of the capacitive sense element.

In embodiments, the electrode is electrically coupled to a high-pass filter (HPF) (232) that comprises a HPF resistance (“R_{HPF}”) and a HPF capacitance (“C_{HPF}”); and the HPF is electrically coupled to a unity gain buffer (234), which generates an output signal (“Vₒ”) of the capacitive sense element circuit.

In embodiments, the test capacitance output and an input of the bootstrap capacitance are electrically coupled between the HPF and the unity gain buffer.

In yet other embodiment(s), a first portion of the output signal of the capacitive sense element circuit represents an external force (e.g., audio signal) that has been applied to a membrane of the capacitive sense element, and a second portion of the output signal of the capacitive sense element circuit represents a measurement of the value of the sense capacitance

In embodiment(s), the bias resistance ranges from about 1 giga-ohm to about 1 tera-ohm. In other embodiment(s), the bias voltage ranges from about 5 volts to about 20 volts.

The MEMS device further comprises a capacitance sensing circuit (112) comprising: a gain circuit (970) comprising a difference circuit (910) and a filter (920); an AC signal source (240) that generates an AC signal (e.g., analog voltage; a digital waveform) at a defined frequency (e.g., being greater than a resonant frequency of the capacitive sense clement; being in a range of about 50 kHz to about 1 MHZ); a demodulator (260) that modulates a first demodulator input and a second demodulator input to obtain a demodulator output (“V_{demod}”) that is electrically coupled, via the gain circuit, to the charge pump input; and a test capacitance (“Cₜ”) (250) comprising a test capacitance input and a test capacitance output.

The AC signal is electrically coupled to the first demodulator input and the test capacitance. The capacitance sensing circuit generates, based on the AC signal at the defined frequency, an AC test voltage (“Vₜ”) at the test capacitance input; and the test capacitance output is electrically coupled to the electrode of the capacitive sense element.

In turn, the capacitive sense element circuit generates, based on the AC test voltage at the defined frequency, the output signal—the output signal being electrically coupled to the second demodulator input and representing a value of the sense capacitance as follows:

$${V}_{o} = {V}_{t} ⋆ {C}_{t} / ( {C}_{MEMS} + {C}_{t} ) .$$

In embodiment(s), the demodulator rectifies Vₒ, e.g., multiplies Vₒ by a square wave at the same phase and frequency as Vₜ), resulting in a DC component of the demodulator output being equal to

$${V}_{d e m o d} = \frac{2}{π} \frac{{V}_{t} {C}_{t}}{( {C}_{MEMS} + {C}_{t} )} .$$

As illustrated by FIG. 9, the demodulator output is electrically coupled to a first input of the difference circuit, and a reference signal (“V_{ref}”) is electrically coupled to a second input of the difference circuit. In turn, a difference output of the difference circuit is electrically coupled, via the filter, to the charge-pump input.

In turn, high DC gain of filter 920 in a feedback loop including filter 920 causes the demodulator output to match, via the difference circuit, the reference signal (e.g., V_{demod}=V_{ref})—generating the nominally constant capacitance value of the sense capacitance equal to

$${C}_{MEMS} + {C}_{t} = \frac{2}{π} {C}_{t} \frac{{V}_{t}}{{V}_{ref}} .$$

Thus, in embodiment(s), a first magnitude of a sum of respective DC component values of the sense capacitance and the test capacitance is inversely proportional to a second magnitude of a second DC component of the reference signal.

In other embodiment(s), the defined frequency is greater than a resonant frequency of the capacitive sense element. In other embodiment(s), the defined frequency is in a range of about 50 kHz to about 1 MHz.

In yet other embodiment(s), a first portion of the output signal of the capacitive sense element circuit represents an external force that has been applied to a membrane of the capacitive sense element, and a second portion of the output signal of the capacitive sense element circuit represents a measurement of the value of the sense capacitance.

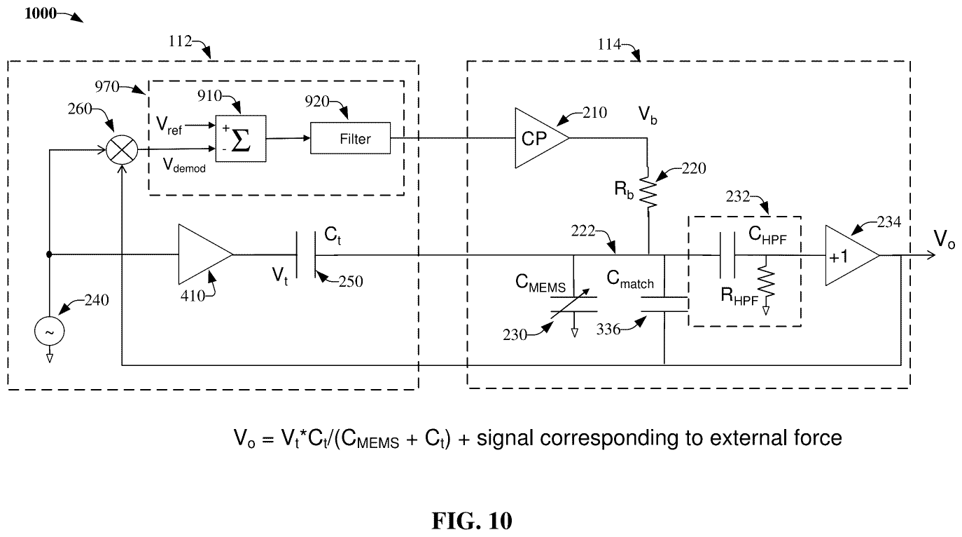

FIG. 10 illustrates a block diagram of a MEMS device circuit (1000) that includes an amplifier (410) electrically coupled to a test capacitance (250)—the MEMS device facilitating maintenance of a nominally constant capacitance value of a sense capacitance of a capacitive sense element (230) of the MEMS device, in accordance with various example embodiments. An amplifier (410) is electrically coupled between the AC signal source (240) and the test capacitance (250); and the amplifier generates, based on the AC signal source, the test voltage (Vₜ).

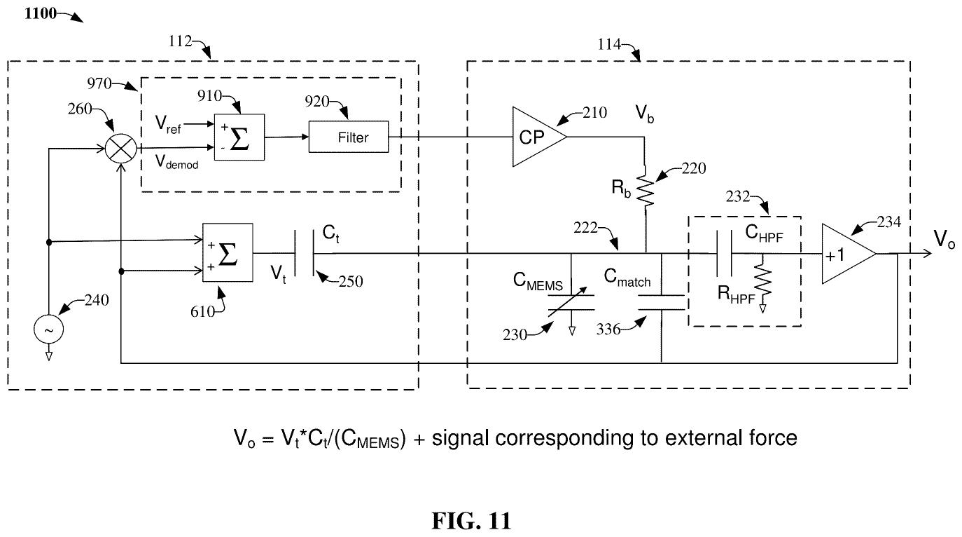

FIG. 11 illustrates a block diagram of a MEMS device circuit (1100) that includes a summing amplifier (610) that is electrically coupled to a test capacitance (250)—the MEMS device circuit facilitating maintenance of a nominally constant capacitance value of a sense capacitance of a capacitive sense element (230) of the MEMS device, in accordance with various example embodiments.

The summing amplifier (610) comprises a first amplifier input, a second amplifier input, and an amplifier output. The first amplifier input is electrically coupled to the AC signal, the second amplifier input is electrically coupled to the output signal of the capacitive sense element circuit, and the amplifier output is electrically coupled to the test capacitance input.

In this regard, the summing amplifier generates the test voltage based on the AC signal and the output signal of the capacitive sense element circuit—the output signal providing, via feedback to the summing amplifier, a positive loop gain <=1.

The, high DC gain of filter 920 in a feedback loop including filter 920 causes the demodulator output to match, via the difference circuit, the reference signal (e.g., V_{demod}=V_{ref})—generating the nominally constant capacitance value of the sense capacitance equal to

$${C}_{MEMS} = \frac{2}{π} {C}_{t} \frac{{V}_{t}}{{V}_{ref}} .$$

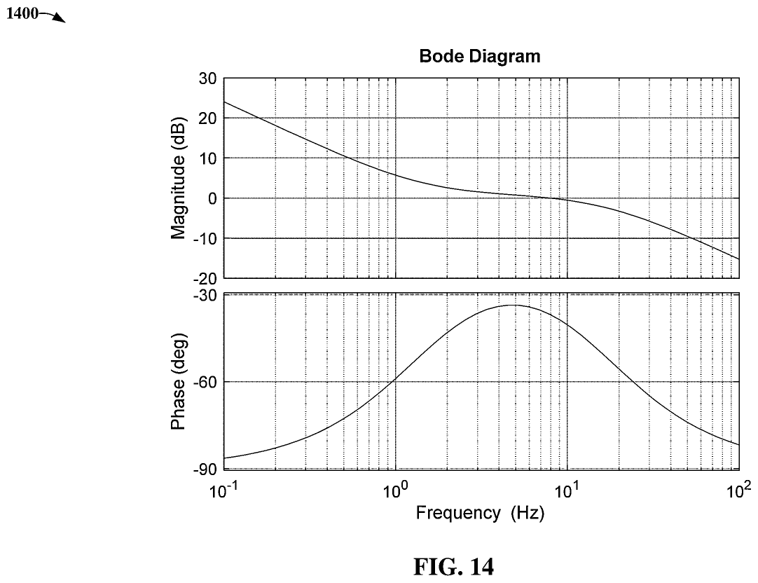

FIG. 14 illustrates a bode diagram (1400) of a constant capacitance filter (920) of a MEMS device (110), in which the MEMS device facilitates maintenance of a nominally constant capacitance value of a sense capacitance of a capacitive sense element of the MEMS device, in accordance with various example embodiments. In embodiment(s), the constant capacitance filter includes an integrator (not shown) to provide high gain at DC summed with and LPF (not shown) to provide a defined phase margin with respect to maintaining closed-loop stability.

In other embodiment(s), a unity gain frequency of the integrator and a bandwidth of the LPF are typically low frequency, e.g., less than 100 Hz; below a low-frequency corner, e.g., −3 dB cutoff point, of a frequency response of the MEMS device.

In yet other embodiment(s), the low frequency corner, or other defined frequency points of the frequency response, are adjusted during startup or overload recovery of the MEMS device, e.g., to enable the MEMS device to settle to a steady state condition within a defined period of time.

In embodiment(s), portion(s) of the constant capacitance filter are digital filters corresponding to discrete-time signals associated with a continuous-time analog signals of the constant capacitance filter, e.g., to satisfy low-frequency time constants corresponding to implementation of the continuous-time analog signals.

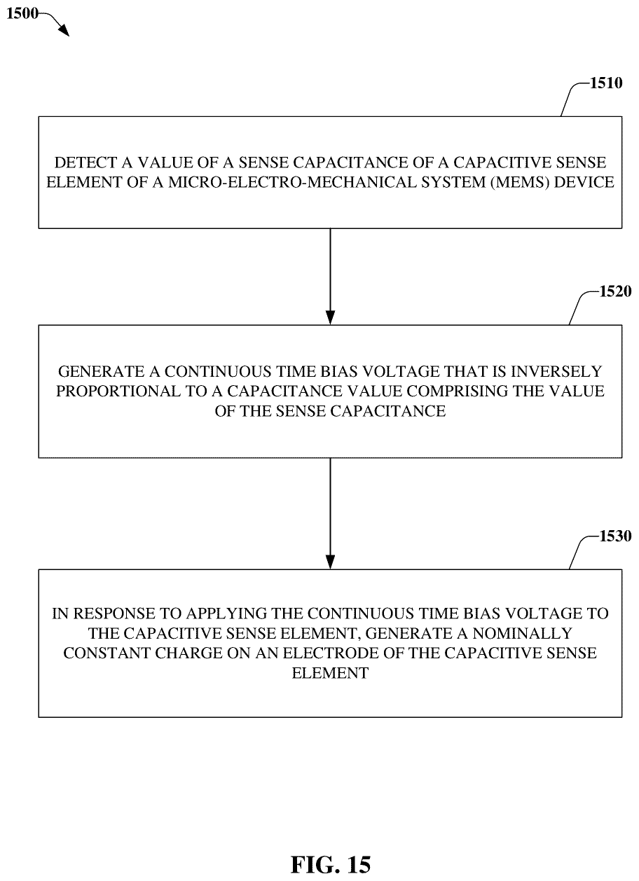

FIG. 15 illustrates a process/methodology in accordance with the disclosed subject matter. For simplicity of explanation, the process/methodology is depicted and described as a series of acts. It is to be understood and appreciated that various embodiments disclosed herein are not limited by the acts illustrated and/or by the order of acts. For example, acts can occur in various orders and/or concurrently, and with other acts not presented or described herein. Furthermore, not all illustrated acts may be required to implement the process/methodology in accordance with the disclosed subject matter. In addition, those skilled in the art will understand and appreciate that the process/methodology could alternatively be represented as a series of interrelated states via a state diagram or events.

Referring again to FIG. 15, a process (1500) performed by a MEMS device (110), e.g., microphone, accelerometer, pressure sensor, ultrasonic receiver, gyroscope, or other type of vibration sensing device, with respect to applying a nominally constant charge to a capacitive sense element of the MEMS device is illustrated, in accordance with various example embodiments. At 1510, a value of a sense capacitance of a capacitive sense element of the MEMS device is detected. At 1520, a continuous time bias voltage that is inversely proportional to a capacitance value comprising the value of the sense capacitance is generated. At 1530, a nominally constant charge on the capacitive sense element is generated in response to the continuous time bias voltage being applied to the capacitive sense element.

In embodiment(s), the value of the sense capacitance is detected by applying an AC test voltage at a defined frequency to a test capacitance input of a test capacitance, in which a test capacitance output of the test capacitance is electrically coupled to the capacitive sense element, and an output signal of the MEMS device represents, based on the AC test voltage at the defined frequency, the value of the sense capacitance.

In other embodiment(s), the applying of the AC test voltage to the test capacitance input further comprises applying the AC test voltage to the test capacitance input in a frequency range of about 50 kHz to about 1 MHz.

In yet other embodiment(s), the method further comprises reducing, via a bootstrap capacitance that is electrically coupled to an output signal of the MEMS device, a noise of the output signal of the MEMS device in response to biasing the capacitance of the capacitive sense clement in a negative capacitance region.

Aspects of circuits, devices, processes, and process blocks explained herein can be embodied within hardware, such as an ASIC, digital logic, or the like. Moreover, the order in which some or all of the process blocks appear in each process should not be deemed limiting. Rather, it should be understood by a person of ordinary skill in the art having the benefit of the instant disclosure that some of the process blocks can be executed in a variety of orders not illustrated.

As it is employed in the subject specification, the terms “circuit” and “device” refer to substantially any analog and/or digital based device(s), circuit(s), etc. comprising, e.g., a micro-electro-mechanical structure, a resistor, a capacitor, a transistor, a diode, an inductor, a memory, a programmable device, e.g., fuse, field programmable gate array (FPGA), complex programmable logic device (CPLD), etc. relevant to performing operations and/or functions of circuit(s), device(s), system(s), etc. disclosed herein.

Reference throughout this specification to “one embodiment,” or “an embodiment,” means that a particular feature, structure, or characteristic described in connection with the embodiment is included in at least one embodiment. Thus, the appearances of the phrase “in one embodiment,” or “in an embodiment,” in various places throughout this specification are not necessarily all referring to the same embodiment. Furthermore, the particular features, structures, or characteristics may be combined in any suitable manner in one or more embodiments.

To the extent that the terms “includes,” “has,” “contains,” and other similar words are used in either the detailed description or the appended claims, such terms are intended to be inclusive-in a manner similar to the term “comprising” as an open transition word-without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Further, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art having the benefit of the instant disclosure.

The above description of illustrated embodiments of the subject disclosure is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A micro-electro-mechanical system (MEMS) device, comprising:
a capacitance sensing circuit comprising
a demodulator comprising a first demodulator input that is electrically coupled to an alternating current (AC) signal source that generates an AC signal at a defined frequency, and
a test capacitance that is electrically coupled to the AC signal; and
a capacitance sense element circuit comprising
a capacitive sense element comprising an electrode and a sense capacitance, and
a charge pump that generates a bias voltage that is electrically coupled, via a bias resistance, to the electrode of the capacitive sense element, wherein the bias voltage is proportional to an inverse value of the sense capacitance, wherein the test capacitance is electrically coupled to the electrode of the capacitive sense element, wherein a capacitance sensing circuit output of the capacitance sensing circuit is electrically coupled to the charge pump, and wherein an output of the capacitive sense element circuit is electrically coupled to a second demodulator input of the demodulator and represents a value of the sense capacitance.

2. The MEMS device of claim 1, wherein the bias voltage facilitates maintenance of a nominally constant charge on the electrode of the capacitive sense element.

3. The MEMS device of claim 2, wherein the capacitance sensing circuit further comprises a gain circuit comprising a low-pass filter that is electrically coupled to a gain stage amplifier of the gain circuit, and wherein the demodulator is electrically coupled, via the gain circuit, to the charge pump.

4. The MEMS device of claim 3, wherein the gain stage comprises a defined gain, and wherein the nominally constant charge is proportional to the defined gain.

5. The MEMS device of claim 1, wherein the capacitance sensing circuit further comprises a gain circuit comprising a difference circuit that is electrically coupled to a filter of the gain circuit, wherein the demodulator is electrically coupled, via the gain circuit, to the charge pump, and wherein the gain circuit facilitates, based on a reference signal, maintenance of a nominally constant capacitance value of the sense capacitance.

6. The MEMS device of claim 5, wherein a demodulator output of the demodulator nominally equals the reference signal to facilitate maintenance of the nominally constant capacitance value of the sense capacitance.

7. The MEMS device of claim 1, where in the capacitive sense element is biased in a negative capacitance region.

8. The MEMS device of claim 7, further comprising:
a bootstrap capacitance that is electrically coupled between the electrode of the capacitive sense element and the output of the capacitive sense element circuit.

9. The MEMS device of claim 8, wherein the bootstrap capacitance facilitates reducing noise of the output of the capacitive sense element circuit in response to the capacitive sense element being biased in the negative capacitance region.

10. The MEMS device of claim 1, wherein the defined frequency is greater than a resonant frequency of the capacitive sense element.

11. The MEMS device of claim 1, wherein a first portion of the output of the capacitive sense element circuit represents an external force that has been applied to a membrane of the capacitive sense element, and wherein a second portion of the output of the capacitive sense element circuit represents a measurement of the value of the sense capacitance.

12. The MEMS device of claim 11, further comprising:
an amplifier that is electrically coupled between the AC signal source and the test capacitance, and that generates, based on the AC signal, the AC test voltage at a test capacitance input of the test capacitance.

13. The MEMS device of claim 12, wherein the amplifier comprises:
a summing amplifier comprising a first amplifier input, a second amplifier input, and an amplifier output, wherein the first amplifier input is electrically coupled to the AC signal, wherein the second amplifier input is electrically coupled to the output of the capacitive sense element circuit, and wherein the amplifier output is electrically coupled to the test capacitance input.

14. The MEMS device of claim 11, wherein an amplitude of the second portion of the output of the capacitive sense element circuit is inversely proportional to the value of the sense capacitance.

15. The MEMS device of claim 1, wherein the capacitive sense element circuit further comprises an inverting buffer that generates an inverted output signal that is based on the output of the capacitive sense element circuit.

16. The MEMS device of claim 15, further comprising:
a difference circuit, wherein a first difference circuit input of the difference circuit is electrically coupled to the output of the capacitive sense element circuit, wherein a second difference circuit input of the difference circuit is electrically coupled to the inverted output signal, and wherein the output of the capacitive sense element circuit is electrically coupled to the second demodulator input via a difference circuit output of the difference circuit.

17. The MEMS device of claim 16, further comprising:
a summing amplifier comprising a first amplifier input, a second amplifier input, and an amplifier output, wherein the first amplifier input is electrically coupled to the AC signal, wherein the second amplifier input is electrically coupled to the output of the capacitive sense element circuit, and wherein the amplifier output is electrically coupled to the test capacitance input.
